(19) United States
(12) Patent Application Publication
(10) Pub. No.: US 2009/0014789 A1
(43) Pub. Date: Jan. 15, 2009

(54) Semiconductor device and method for manufacturing the same

(75) Inventor: Kazutaka Manabe, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/216,904

(22) Filed: Jul. 11, 2008

(30) Foreign Application Priority Data
Jul. 13, 2007 (JP) 2007-184548

(51) Int. Cl. H01L 27/108; H01L 21/8242

(52) U.S. Cl. 257/334; 438/270; 257/E27.084; 257/E21.646

(57) ABSTRACT

A semiconductor device comprising a recessed transistor coexists with P-N gate planar-type transistors, wherein high-concentration impurity-diffused material 9 is buried in a polysilicon film, which is the gate electrode of the recessed transistor, in order to suppress the reduction of ON current caused by a depletion phenomenon of the recessed gate of the recessed transistor, and to prevent increase in variation of the threshold voltage of the planar-type transistor composed of the P or N gate of a conductivity type different from the conductivity type of the recessed transistor.

This application is based upon and claims the benefit of priority from Japanese patent application No. 2007-184548, filed on Jul. 13, 2007, the disclosure of which is incorporated herein in its entirety by reference.

### BACKGROUND OF THE INVENTION

1. Field of the Invention

The present invention relates to a semiconductor device, and specifically, a semiconductor device comprising a recessed transistor and N and P-gate planar-type transistors (NMOS/PMOS), wherein a high-concentration impurity-diffused material is buried into a recessed gate electrode. The present invention also relates to a method for manufacturing a semiconductor device wherein a high-concentration impurity-diffused material is buried in a recessed gate electrode.

2. Related Art

In recent years, with the miniaturization of DRAM for example, a growing number of recessed transistors are used for a cell transistor. This is because the gate length of the recessed transistor can be elongated compared with a planar-type transistor, which is advantageous for the miniaturization of the cell.

However, when the peripheral transistors of a planer type are formed into P-N gates in addition to the cell transistors which are recessed transistors, a problem is caused in introducing an impurity into each gate electrode. For example, when a recessed transistor has an. N-gate, it is conceivable to form a non-doped polysilicon film over the entire surface of a wafer, and thereafter to introduce phosphorus ions into the gate electrodes of the recessed cell transistor and peripheral NMOS to form an N-gate, while boron ions are introduced into the gate electrodes of the peripheral PMOS to form a P-gate. At this time, it is difficult to introduce phosphorus to the bottom of the recess gate of the recessed cell transistor. This is because if high implantation energy is set, impurity ions reach the channel region of the peripheral NMOS. Since the implantation energy cannot be high, ON current is reduced due to the depletion phenomenon of the gate electrodes of the recessed cell transistor, and insufficiently introduced phosphorus causes variation of the concentration as a matter of course, which increases variation of the threshold voltage of the recessed cell transistor.

In order to solve such problems, it is conceivable to form a previously phosphorus-doped polysilicon film over the entire surface of the wafer, and thereafter to implant higher dose of boron ions into the gate electrodes of the peripheral PMOS to cancel out n-type phosphorus and form a P-gate. However, since there is a phenomenon that boron leaks to the channel region of the substrate due to the thermal diffusion during the manufacturing process, it is difficult to hit back high-dose boron at the P-gate. The insufficient introduction of boron into the P-gate causes a problem of large variation of PMOS threshold voltage.

Specifically, when cell transistors including recessed transistors coexist with planar-type transistors constituted by P-N gates, it is difficult to make both the recessed cell transistors and the peripheral PMOS have stable characteristics.

On the other hand, a technique is disclosed in Patent Document 1 (Japanese Patent Application Laid-Open No. 5-55593), in which, in manufacturing an insulated-gate type field effect transistor, a phosphorus glass film is formed on a gate insulation film formed on a semiconductor substrate, gate electrodes are formed thereon, and phosphorus is diffused from the phosphorus glass film into the drain region in the semiconductor substrate under the gate insulation film to form a high-concentration diffused layer.

### SUMMARY OF THE INVENTION

In a semiconductor device having a coexisting recessed transistor and planar-type transistor constituted by a P-N gate, it is an object of the present invention to suppress the reduction of ON current due to the depletion phenomenon of a recessed gate in the recessed transistor, and to prevent increase in the variation of the threshold voltage of the planar-type transistor of P or N gate that has a conductivity type different from the recessed transistor.

Specifically, the present invention relates to a semiconductor device comprising a recessed transistor, a P-gate planar-type transistor and an N-gate planar-type transistor on a semiconductor substrate,

wherein the recessed transistor comprises, as a recessed gate electrode, a polysilicon film in which a high-concentration impurity-diffused material is buried.

The present invention also relates to a method for manufacturing a semiconductor device comprising a recessed transistor, a P-gate planar-type transistor and an N-gate planar-type transistor on a semiconductor substrate, comprising:

(1) forming an element isolating region that isolates regions for forming the recessed transistor, the P-gate planar-type transistor, and the N-gate planar-type transistor in the substrate;

(2) forming a recess for a gate electrode in the region for forming the recessed transistor;

(3) forming a gate insulation film over the entire surface of the substrate;

(4) forming a film of a first non-doped polysilicon over the entire surface of the substrate leaving a gap for burying a high-concentration impurity-diffused material in the recess in subsequent process steps;

(5) forming a film of the high-concentration impurity-diffused material over the entire surface of the substrate, burying the high-concentration impurity-diffused material in the gap, and thereafter removing the high-concentration impurity-diffused material on the surface of the substrate;

(6) forming a film of a second non-doped polysilicon over the entire surface of the substrate;

(7) selectively implanting ions of a first impurity of the same conductivity type as the conductivity type of the recessed transistor into the second non-doped polysilicon over the recessed transistor and the region for forming the P or N gate planar-type transistor having the same conductivity type as the conductivity type of the recessed transistor;

(8) selectively implanting ions of a second impurity of the different conductivity type from the conductivity type of the recessed transistor into the second non-doped polysilicon over the region for forming the P or N gate planar-type transistor having the different conductivity type from the conductivity type of the recessed transistor; and

(9) processing the gate insulation film and the first and second polysilicon films into a shape of respective gate electrodes.

According to the present invention, a high-concentration impurity-diffused material is buried in the recessed gate of a recessed transistor. This is advantageous in that a required impurity can be sufficiently introduced into the bottom portion of the recessed gate, and even when the peripheral transistors are formed into a P-N gate, the characteristics and the manufacturing method of the peripheral transistor can be kept the same as the case where no recessed transistor is present, and it is possible to avoid the reduction of ON current and increase in the variation of the threshold voltage caused by the depletion phenomenon of the gate electrode of the recessed transistor.

### BRIEF DESCRIPTION OF THE DRAWINGS

FIG. 1 is a sectional view that shows the configuration of a semiconductor device (DRAM) according to an exemplary embodiment of the present invention; and

FIGS. 2A to 2F are sectional views that show an example of the manufacturing process according to the present invention.

### DETAILED DESCRIPTION OF THE PREFERRED EMBODIMENTS

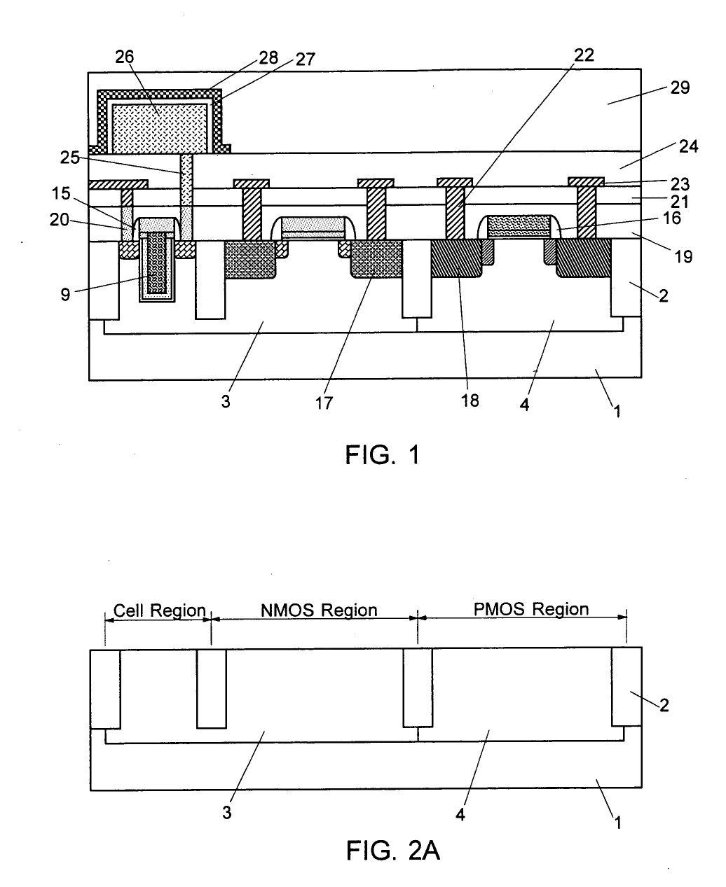

An exemplary embodiment of the present invention will be described referring to the drawings. As shown in FIG. 1, the semiconductor device of the exemplary embodiment is characterized in that high-concentration impurity-diffused material 9 is buried in a recessed gate electrode.

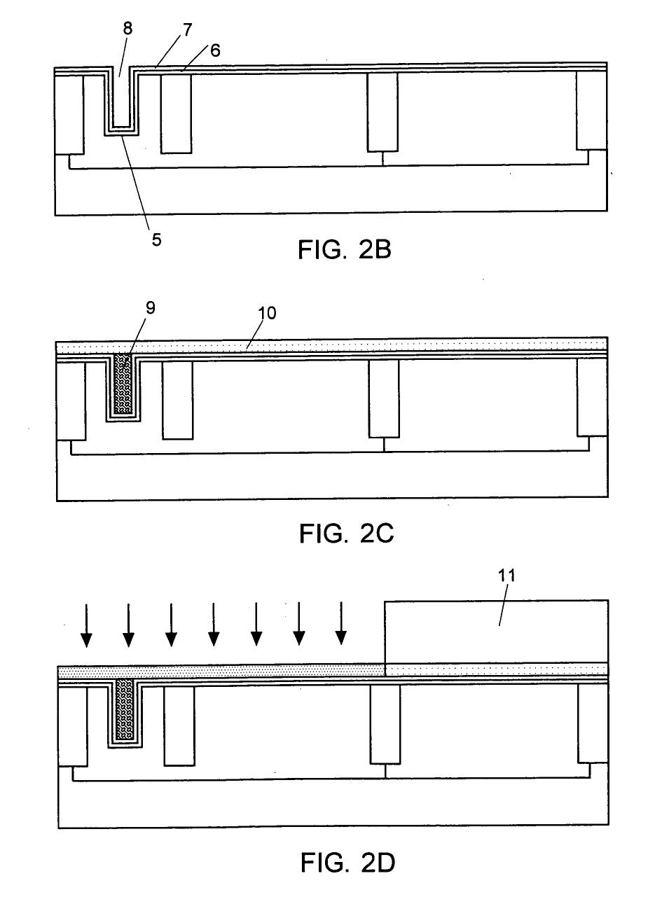

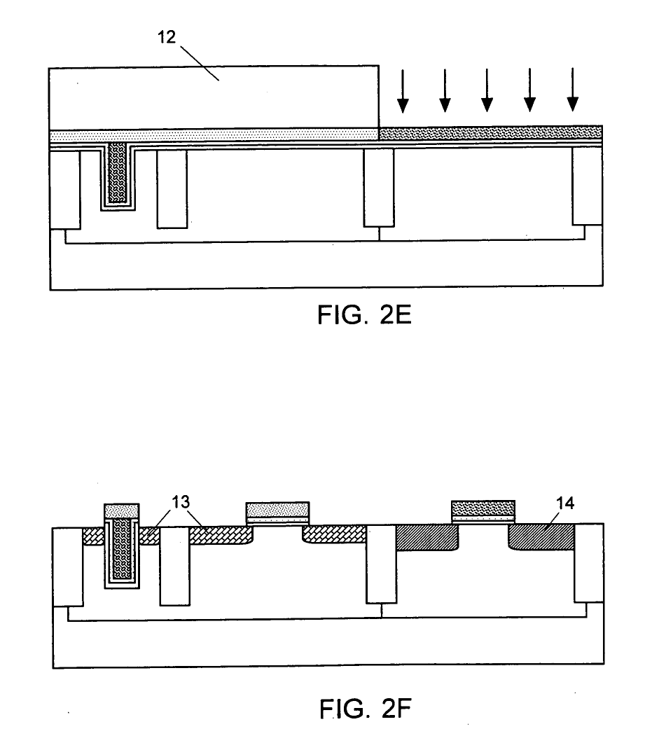

A method for manufacturing the semiconductor device shown in FIG. 1 will be described referring to FIGS. 2A to 2F. In each of these drawings, a sectional view wherein a region for forming a recessed transistor to be a cell transistor (cell region) is disposed in the left; a region for forming an NMOS transistor (NMOS region) is disposed in the center; and a region for forming a PMOS transistor (PMOS region) is disposed in the right. The NMOS transistor and the PMOS transistor compose a CMOS of a peripheral circuit. Although a contact on the side of a bit line is typically shared by two cell transistors, only one cell transistor is shown for the simplification of the drawing.

FIG. 2A is a diagram showing that element isolating regions 2 are formed on the surface of P-type semiconductor substrate 1, P-well 3 is formed in the cell region and the NMOS region, and N-well 4 is formed in the PMOS region using an ordinary method.

Next, recess 5 of the recessed cell transistor is formed using an ordinary method, and gate insulation film 6 is formed over the entire surface of the substrate using, for example, thermal oxidation. Then, first non-doped silicon film 7 is formed in a thickness of, for example, 15 nm when the width of the recess is, for example, 80 nm depending on the width of previously formed recess. Here, as shown in FIG. 2B, recess 5 is not completely buried in first non-doped silicon film 7 leaving gap 8.

Then, using CVD or the like, phosphorus glass film of, for example, a phosphorus concentration of 5 mol %, of a thickness of 40 nm is formed over the entire surface of the substrate, and the surface phosphorus glass layer is etched back to bury phosphorus glass 9, which is a high-concentration impurity-diffused material, in gap 8. Thereafter, second non-doped silicon film 10 of, for example, 60 nm in thickness is formed to obtain a structure shown in FIG. 2C.

Next, using lithography, the PMOS region is coated with a photoresist film 11, and phosphorus ions are selectively implanted into the cell region, which is an NMOS, and non-doped polysilicon, which is the gate electrode material of the NMOS region under conditions of, for example, several keV and several e15 cm⁻² (FIG. 2D). Then, the cell region and the NMOS region are coated with photoresist film 12, and boron ions are implanted into the PMOS region under conditions of, for example, several keV and several e15 cm⁻² (FIG. 2E). Here, the impurity introduced by ion implantation does not sufficiently reach the interface to the gate insulation film. Thereafter, a metal or alloy layer, such as tungsten and tungsten silicide, is generally formed on the surface to decrease the resistance of gate wiring; however, since this is not essential for the present invention, the description thereof will be omitted.

Then, the first and second polysilicon films on the surface are patterned to desired patterns and are formed into the shapes of gate electrodes in respective regions, and an N-diffusion layer or a P-diffusion layer is formed as required (generally called as an extension region). A halo (pocket) layer can also be applied as required. In FIG. 2F, N⁻ diffusion layer 13 in the cell region and the NMOS region, and P⁻ diffusion layer 14 in the PMOS region are simply shown.

Thereafter, general processes for forming, for example, sidewalls, source-drains, interlayer insulation films, contacts, wirings, are sequentially performed, and for example, a DRAM shown in FIG. 1 is formed (upper wiring and the like are not shown for simplification).

Here, the impurity in the upper portion of the gate electrode is diffused to the interface with the gate insulation film by heat treatment, such as the activation of the source and the drain and the reflow in the formation of the interlayer insulation film. Particularly in the recessed transistor, phosphorus is diffused from the phosphorus glass 9 buried in the polysilicon film, and the impurity of a sufficient concentration is also introduced into the interface with the gate insulation film of the gate electrode in the recess.

In FIG. 1, reference numeral 15 denotes a cell portion sidewall, 16 denotes peripheral portion sidewalls, 17 denotes an N⁺ source-drain, 18 denotes a P⁺ source-drain, 19 denotes a first interlayer insulation film, 20 denotes cell contacts, 21 denotes a second interlayer insulation film, 22 denotes contacts, 23 denotes wirings, 24 denotes a third interlayer insulation film, 25 denotes a capacitor contact, 26 denotes a capacitor accumulation electrode, 27 denotes a capacitor insulation film, 28 denotes an opposite electrode, and 29 denotes a fourth interlayer insulation film.

In the above-described example, although an insulating material that contains a high-concentration impurity, particularly phosphorus glass is used as the high-concentration impurity-diffused material, high-concentration phosphorus-doped silicon may also be used. The concentration of phosphorus may be for example, 1e20 to 8e20 cm⁻³.

Although the first polysilicon film on the surface of the substrate is exposed by etching back when the high-concentration impurity-diffused material is buried in the recess, chemical-mechanical polishing (CMP) process can also be applied instead of the etch back process.

Although an example wherein the recessed transistor is an NMOS is shown in the above example, an insulating material that contains high-concentration boron (e.g. boron glass) or boron-doped polysilicon may also be used as the high-concentration impurity-diffused material when the recessed transistor is a PMOS.

Although an example wherein a recessed transistor is used as the cell transistor of the DRAM is shown, the present invention is not limited thereto, but can be applied to any semiconductor devices as long as a recessed transistor coexists with a P-N gate CMOS.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

What is claimed is:

1. A semiconductor device comprising a recessed transistor, a P-gate planar-type transistor and an N-gate planar-type transistor on a semiconductor substrate,
wherein the recessed transistor comprises, as a recessed gate electrode, a polysilicon film in which a high-concentration impurity-diffused material is buried.

2. The semiconductor device according to claim 1,
wherein the high-concentration impurity-diffused material is an insulation material that contains a high-concentration impurity, or high-concentration impurity-doped polysilicon.

3. The semiconductor device according to claim 2,
wherein the recessed transistor is an NMOS, and phosphorus glass is buried as the high-concentration impurity-diffused material.

4. The semiconductor device according to claim 1,
wherein the semiconductor device is a DRAM, the recessed transistor is a cell transistor, and the P and N gate planar-type transistors constitute a CMOS of a peripheral circuit.

5. A method for manufacturing a semiconductor device comprising a recessed transistor, a P-gate planar-type transistor and an N-gate planar-type transistor on a semiconductor substrate, comprising:
(1) forming an element isolating region that isolates regions for forming the recessed transistor, the P-gate planar-type transistor, and the N-gate planar-type transistor in the substrate;
(2) forming a recess for a gate electrode in the region for forming the recessed transistor;
(3) forming a gate insulation film over the entire surface of the substrate;
(4) forming a film of a first non-doped polysilicon over the entire surface of the substrate leaving a gap for burying a high-concentration impurity-diffused material in the recess in subsequent process steps;
(5) forming a film of the high-concentration impurity-diffused material over the entire surface of the substrate, burying the high-concentration impurity-diffused material in the gap, and thereafter removing the high-concentration impurity-diffused material on the surface of the substrate;
(6) forming a film of a second non-doped polysilicon over the entire surface of the substrate;
(7) selectively implanting ions of a first impurity of the same conductivity type as the conductivity type of the recessed transistor into the second non-doped polysilicon over the recessed transistor and the region for forming the P or N gate planar-type transistor having the same conductivity type as the conductivity type of the recessed transistor;
(8) selectively implanting ions of a second impurity of the different conductivity type from the conductivity type of the recessed transistor into the second non-doped polysilicon over the region for forming the P or N gate planar-type transistor having the different conductivity type from the conductivity type of the recessed transistor; and
(9) processing the gate insulation film and the first and second polysilicon films into a shape of respective gate electrodes.

6. The method for manufacturing a semiconductor device according to claim 5, wherein the high-concentration impurity-diffused material is an insulation material that contains a high-concentration impurity, or high-concentration impurity doped polysilicon.

7. The method for manufacturing a semiconductor device according to claim 6, wherein the recessed transistor is an NMOS, and phosphorus glass is buried as the high-concentration impurity-diffused material.

8. The method for manufacturing a semiconductor device according to claim 5, wherein the semiconductor device is a DRAM, the recessed transistor is a cell transistor, and the P and N gate planar-type transistors constitute a CMOS of a peripheral circuit.
